(19) United States
(12) Patent Application Publication
(10) Pub. No.: US 2013/0329367 A1
(43) Pub. Date: Dec. 12, 2013

(54) ELECTRONIC DEVICE HAVING HEAT-DISSIPATING STRUCTURE

(71) Applicants: SZU-HAO HUANG, NEW TAIPEI CITY (TW); SHIH-PO LO, NEW TAIPEI CITY (TW)

(72) Inventors: SZU-HAO HUANG, NEW TAIPEI CITY (TW); SHIH-PO LO, NEW TAIPEI CITY (TW)

(73) Assignee: ASKEY COMPUTER CORP.

(21) Appl. No.: 13/563,771

(22) Filed: Aug. 1, 2012

(30) Foreign Application Priority Data
Jun. 7, 2012 (TW) 101120499

(51) Int. Cl. H05K 7/20

(52) U.S. Cl. 361/704

(57) ABSTRACT

An electronic device having a heat-dissipating structure includes a housing, a printed circuit board, a heat-dissipating element, and a thermal conductive element. The housing has an opening and internally defines a receiving space. The printed circuit board is located in the receiving space and has an electronic component mounted thereon. The heat-dissipating element has a first surface and an opposing second surface, and is disposed above the printed circuit board to locate in the receiving space of the housing wile the first surface is exposed from the housing via the opening. The thermal conductive element is disposed between the heat-dissipating element and the electronic component for transferring heat generated by the electronic component to the heat-dissipating element, so that the heat is directly dissipated into ambient air via the opening. Accordingly, heat produced by the electronic component can be efficiently removed without accumulating in the electronic device.

### CROSS-REFERENCE TO RELATED APPLICATION

This non-provisional application claims priority under 35 U.S.C. §119(a) on Patent Application No(s). 101120499 filed in Taiwan, R.O.C. on Jun. 7, 2012, the entire contents of which are hereby incorporated by reference.

### FIELD OF TECHNOLOGY

The present invention relates to an electronic device, and more particularly to an electronic device having heat-dissipating structure.

### BACKGROUND

Many currently available electronic devices have constantly improved functions. To perform these functions, electronic components in the electronic devices have to execute high-speed computation and multiplexing process. These electronic components produce a large amount of heat while they operate to thereby cause a largely raised environment temperature in the electronic devices. Such high-temperature environment adversely reduces the performance of the electronic components or even causes damaged electronic components. Please refer to FIG. 1. To protect an electronic device against lowered performance due to excessively high interior temperature thereof, a heat-dissipating pad 6 is usually disposed above a heat-producing electronic component 4 mounted on a printed circuit board (PCB) 2 in the electronic device. The PCB 2 with the electronic component 4 and the heat-dissipating pad 6 mounted thereon is then arranged in between an upper housing 8 and a lower housing 10 of the electronic device. Further, the upper housing 8 of the electronic device is provided with heat-dissipation vents 82 to help in the heat dissipation of the electronic component 4.

However, due to the miniaturization of the electronic devices, many electronic devices either have a very limited interior space that is insufficient for dissipating heat via convective heat transfer or are not provided with heat dissipation vents due to specific appearance design requirement. Under these circumstances, the heat produced by the electronic components just could not be effectively removed from the electronic devices. Moreover, since the upper and lower housings of the electronic devices are usually made of plastic materials with high thermal resistance and accordingly poor heat conductivity, the heat produced by the operating electronic components tends to accumulate in the electronic devices to result in overheated and damaged electronic components as well as deteriorated overall performance of the electronic devices.

It is therefore tried by the inventor to develop an electronic device having heat-dissipating structure, so that heat produced by an electronic component in the electronic device can be effectively dissipated into ambient air to avoid the problems of lowered performance or failure of the electronic device due to accumulated heat therein.

### SUMMARY

A primary object of the present invention is to provide an electronic device having heat-dissipating structure, so that heat produced by an electronic component in the electronic device can be directly dissipated into ambient air by way of heat conduction.

To achieve the above and other objects, the electronic device having heat-dissipating structure according to the present invention includes a housing, a printed circuit board (PCB), a heat-dissipating element, and a thermal conductive element. The housing is formed with an opening and internally defines a receiving space. The PCB is disposed in the receiving space and has a heat-producing electronic component mounted thereon. The heat-dissipating element has a first surface and a second surface opposite to the first surface; and is disposed above the PCB to locate in the receiving space in the housing with the first surface exposed from the housing via the opening. The thermal conductive element is disposed between the heat-dissipating element and the electronic component for transferring heat produced by the electronic component to the heat-dissipating element, so that the heat can be directly dissipated from the heat-dissipating element via the opening into ambient air outside the housing to achieve the purpose of removing heat from the electronic component.

With the particularly arrangements of the housing with an opening, the heat-dissipating element, the thermal conductive element and the PCB for the electronic device according to the present invention, heat produced by the electronic component during operation thereof can be transferred to the heat-dissipating element and be directly dissipated from the heat-dissipating element via the opening into ambient air outside the housing, enabling high-efficient removal of heat from the electronic component.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view schematically showing the heat-dissipating measures for a conventional electronic device;

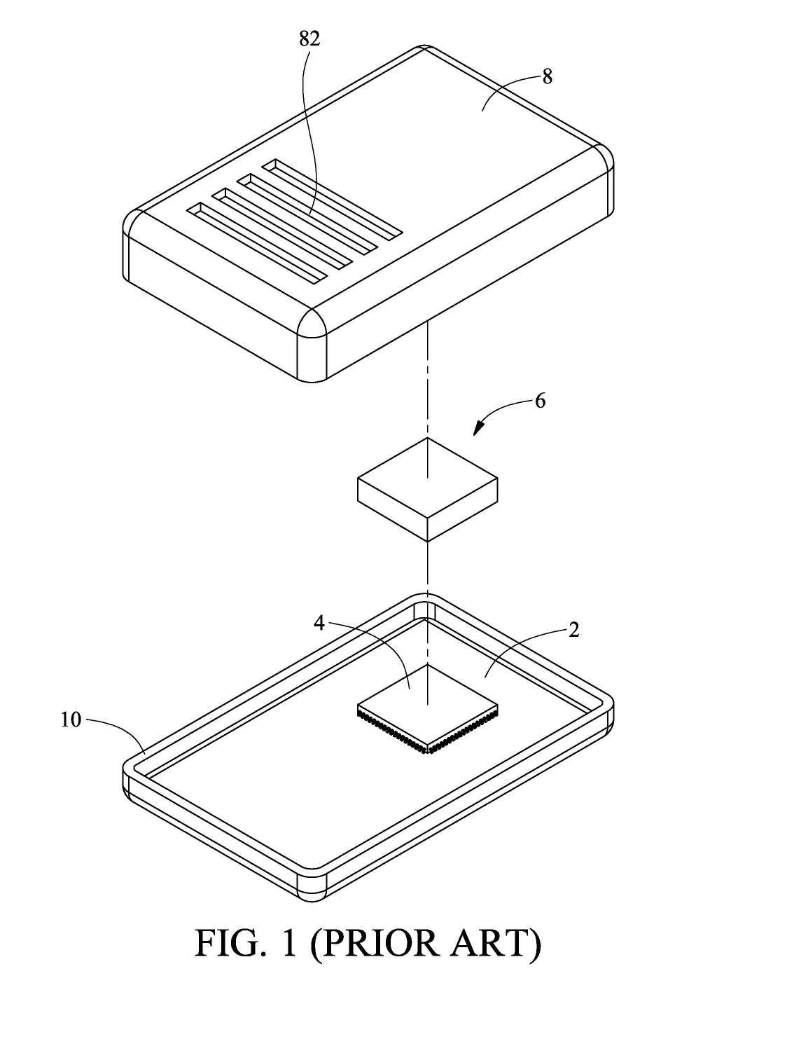

FIG. 2 is an exploded perspective view schematically showing an electronic device having heat-dissipating structure according to a first embodiment of the present invention;

FIG. 3 is an assembled view of FIG. 2;

FIG. 4 is a sectional view taken along line A-A of FIG. 3; and

FIG. 5 is an assembled perspective view of an electronic device having heat-dissipating structure according to a second embodiment of the present invention.

### DETAILED DESCRIPTION

The present invention will now be described with some preferred embodiments thereof and with reference to the accompanying drawings. For the purpose of easy to understand, elements that are the same in the preferred embodiments are denoted by the same reference numerals.

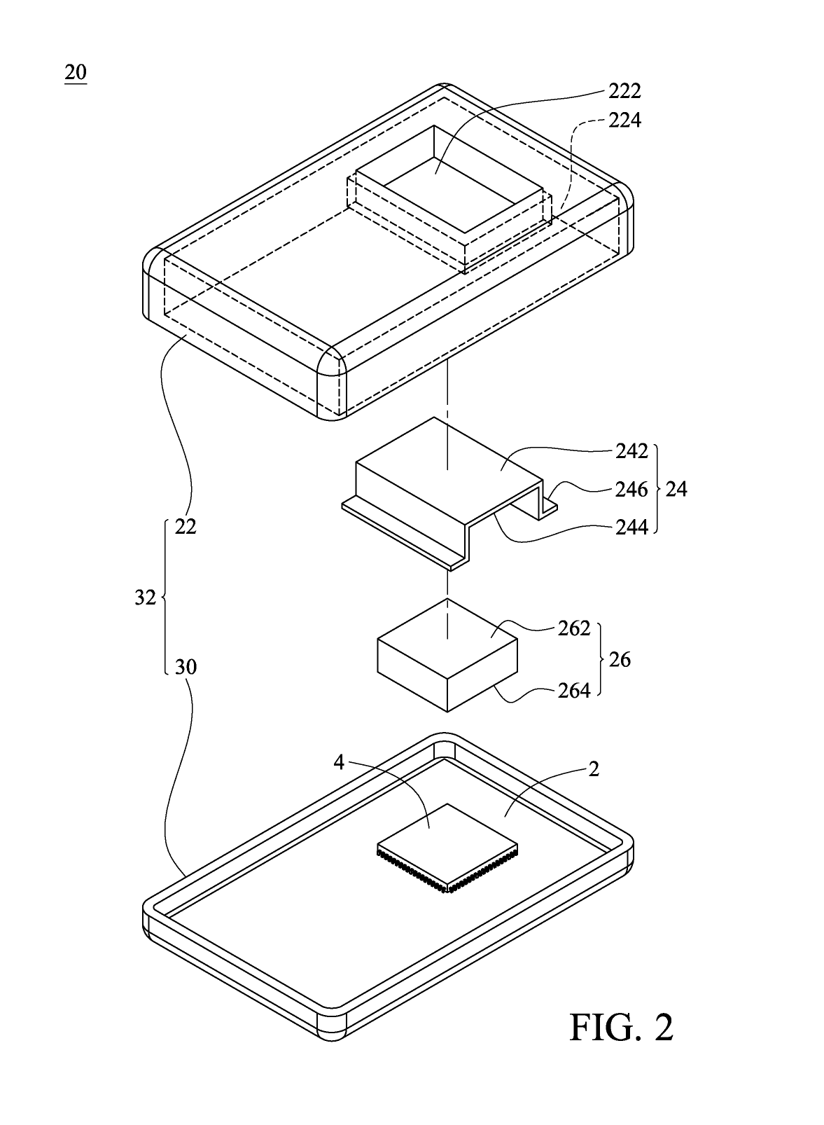

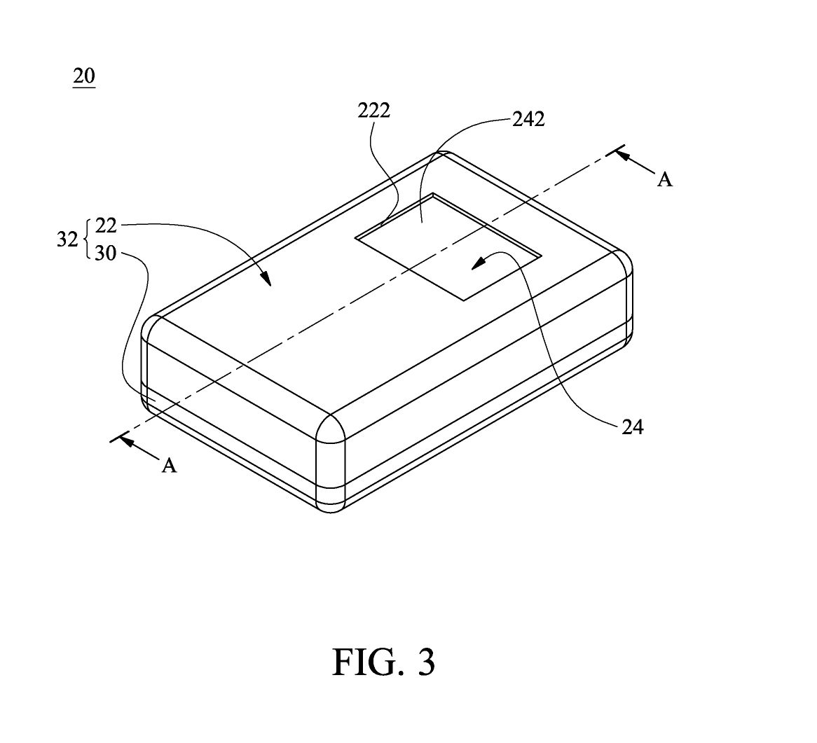

Please refer to FIGS. 2 and 3 that are exploded and assembled perspective views, respectively, schematically showing an electronic device having heat-dissipating structure according to a first embodiment of the present invention, and to FIG. 3 that is a sectional view taken along line A-A of FIG. 3. For the purpose of conciseness, the present invention is also briefly referred to as “the electronic device” herein. As can be seen in FIG. 2, the electronic device in the first embodiment is generally denoted by reference numeral 20, and includes a housing 32, a printed circuit board (PCB) 2, a heat-dissipating element 24 and a thermal conductive element 26 to enable effective dissipation of heat produced by an electronic component 4 mounted on the PCB 2 into ambient air.

The housing 32 is formed with an opening 222 and internally defines a receiving space 224. In the first embodiment, the housing 32 is illustrated as including a first housing 22 and a second housing 30, which are closed to each other to define the receiving space 224 between them for receiving the heat-dissipating element 24, the thermal conductive element 26, the PCB 2 and the electronic component 4 therein.

The opening 222 is formed on the first housing 22. In the present invention, the first housing 22 is illustrated as an upper housing of the electronic device 20 and the opening 222 is directly integrally formed on the upper housing. Further, the housing 32 is made of a plastic material.

While the opening 222 is illustrated in the first embodiment as being formed on the first housing 22 at a position directly corresponding to the position of an electronic component 4 on the PCB 2 that requires heat dissipation, it is understood the opening 222 is not always necessarily arranged at a position directly corresponding to that of the electronic element 4. Further, the opening 222 may have a shape and size other than those shown in the illustrated first embodiment and the drawings. The configuration of the opening 222 can be changed according to actual need in use.

The heat-dissipating element 24 has a first surface 242 and a second surface 244 opposite to the first surface 242. The heat-dissipating element 24 is disposed on the PCB 2 to locate in the receiving space 224 defined by the housing 32, such that the first surface 242 is exposed from the first housing 22 of the housing 32 via the opening 222, as shown in FIG. 3. In this case, the first surface 242 may have a size smaller than or equal to that of the opening 222.

The heat-dissipating element 24 may be pre-fixed onto the first housing 22 or the PCB 2. For example, the heat-dissipating element 24 may be directly bonded to the first housing 22 using a fast-acting adhesive or a back adhesive, or be fixed to the PCB 2 as a surface mounted device (SMD).

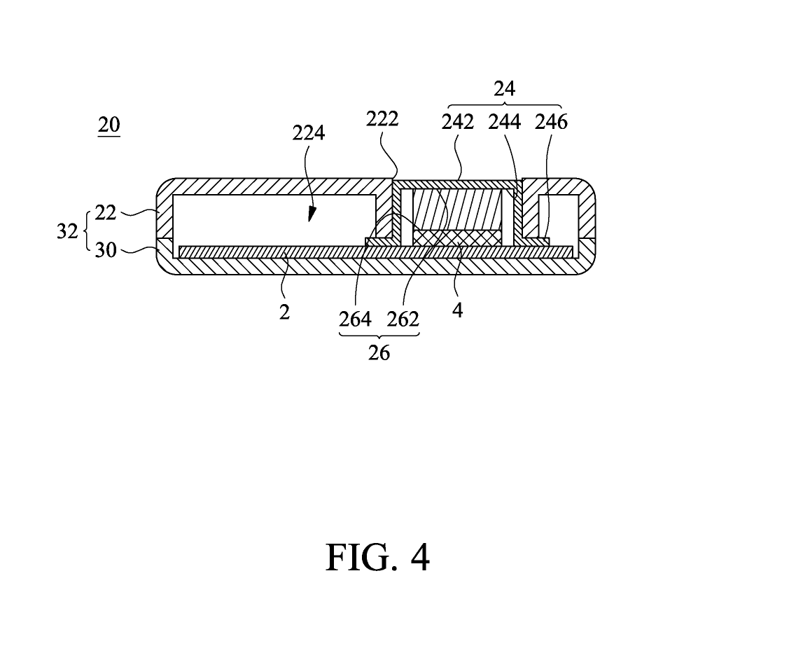

Alternatively, instead of being bonded to the first housing 22 or fixed to the PCB 2, the heat-dissipating element 24 can be simply clamped between the housing 32 and the PCB 2 and confined in the opening 222 when the heat-dissipating element 24, the thermal conductive element 26 and the PCB 2 are stacked from top to bottom in the housing 32. In this case, as can be seen in FIGS. 2 and 4, two wing portions 246 are further symmetrically formed on two lateral outer surfaces of the heat-dissipating element 24 for engaging with the first housing 22, such that the heat-dissipating element 24 is confined to the opening 222 on the first housing 22 without the risk of separating from the first housing 22 via the opening 222.

Any mounting manner that enables the heat-dissipating element 24 to be firmly and stably held to the opening 222 without arbitrarily moving in and relative to the opening 222 shall fall in the scope of the present invention. The heat-dissipating element 24 may be in the form of a metal hood or a plate-type heat dissipating member. In the first embodiment, the heat-dissipating element 24 is illustrated as a metal hood, which internally defines a receiving space for accommodating the electronic component 4 therein.

Please refer to FIGS. 2 and 4 at the same time. The thermal conductive element 26 is disposed between the heat-dissipating element 24 and the electronic component 4 to locate in the receiving space defined by the heat-dissipating element 24. The thermal conductive element 26 has one surface 262 in contact with the second surface 244 of the heat-dissipating element 24 and another opposite surface 264 in contact with the electronic component 4. More specifically, after the heat-dissipating element 24 is covered over the electronic component 4, the heat produced by the electronic component 4 is transferred via the thermal conductive element 26 to the heat-dissipating element 24. The heat is then transferred to the first surface 242 of the heat-dissipating element 24 exposed from the opening 222 of the first housing 22 and directly dissipates into ambient air outside the housing 32 to achieve the purpose of heat dissipation.

The thermal conductive element 26 can be any one of a type of thermal grease, a thermal pad, a heat-conducting post or a heat-conducting block. The thermal conductive element 26 may have a thickness selected according to a space between the heat-dissipating element 24 and the electronic component 4. For example, the thermal conductive element 26 may have a thickness equal to the space between the heat-dissipating element 24 and the electronic component 4, so that the heat produced by the electronic component 4 can be absorbed by the thermal conductive element 26 that tightly contacts with the electronic component 4. And then, the heat can be further transferred from the thermal conductive element 26 to the heat-dissipating element 24 that also tightly contacts with the thermal conductive element 26. Finally, the heat directly dissipates from the first surface 242 of the heat-dissipating element 24 into ambient air outside the housing 32 and is carried away from the electronic device 20 through air convection and heat exchange in external environment. In this manner, the heat produced by the electronic component 4 can be effectively removed to lower the temperature in the receiving space 224 in the housing 32 and accordingly, protect the electronic component 4 against damage or reduced performance due to accumulated heat in the housing 32.

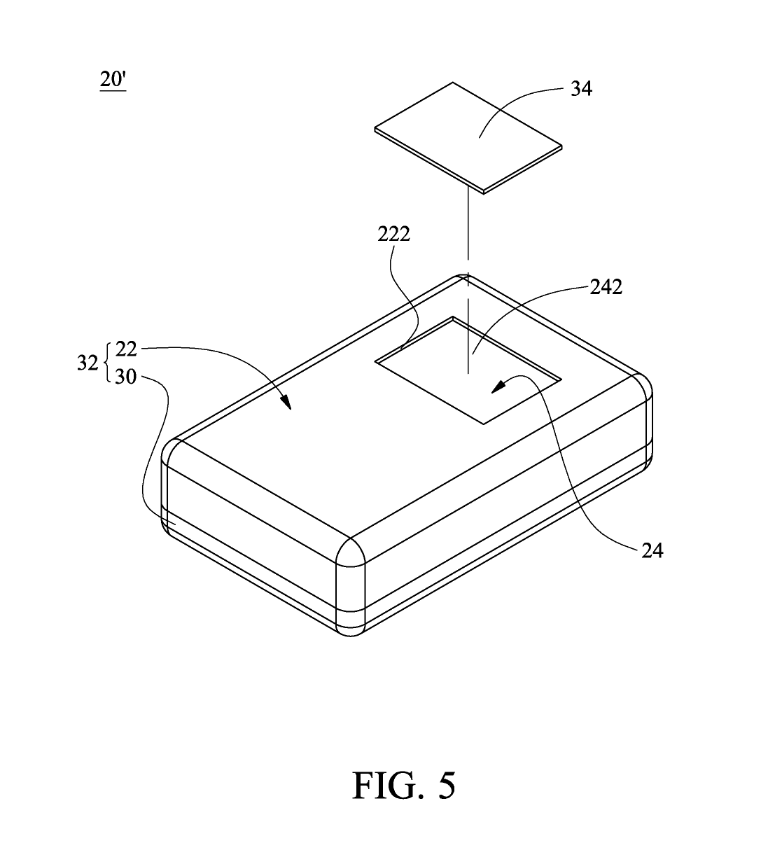

FIG. 5 is an assembled perspective view schematically showing an electronic device having heat-dissipating structure according to a second embodiment of the present invention. The electronic device in the second embodiment is generally denoted by reference numeral 20′ and includes a housing 32, a PCB (not shown in FIG. 5), a heat-dissipating element 24 and a thermal conductive element (not shown in FIG. 5), just the same as the electronic device 20 in the first embodiment. However, the second embodiment is different from the first embodiment in further having an identification member 34 provided on the first surface 242 of the heat-dissipating element 24. The identification member 34 is exposed from the housing 32 via the opening 222 to serve as an identification label of the electronic device 20′. For example, the identification member 34 can be a mark representing a product, a logo of a corporation, a safety certificate, a specification label, a barcode label or the like. Therefore, the opening 222 not only helps the heat-dissipating element 24 to provide high-efficient heat dissipation effect, but also provides a good place for showing the identification member 34.

With the particularly arrangements of the housing with an opening, the heat-dissipating element, the thermal conductive element and the PCB for the electronic device according to the present invention, heat produced by the electronic component during operation thereof can be transferred to the heat-dissipating element and be directly dissipated from the heat-dissipating element into ambient air outside the housing via the opening, enabling high-efficient removal of heat from the electronic component.

The present invention has been described with some preferred embodiments thereof and it is understood that many changes and modifications in the described embodiments can be carried out without departing from the scope and the spirit of the invention that is intended to be limited only by the appended claims.

What is claimed is:

1. An electronic device having heat-dissipating structure, comprising:
a housing being formed with an opening and internally defining a receiving space;
a printed circuit board (PCB) being disposed in the receiving space and having a heat-producing electronic component mounted thereon;
a heat-dissipating element having a first surface and a second surface opposite to the first surface; and the heat-dissipating element being disposed above the PCB to locate in the receiving space in the housing with the first surface exposed from the housing via the opening; and
a thermal conductive element being disposed between the heat-dissipating element and the electronic component for transferring heat produced by the electronic component to the heat-dissipating element, so that the heat can be directly dissipated from the heat-dissipating element via the opening into ambient air outside the housing to achieve the purpose of removing heat from the electronic component.

2. The electronic device having heat-dissipating structure as claimed in claim 1, wherein the heat-dissipating element further includes two wing portions formed on outer surfaces of the heat-dissipating element for correspondingly engaging with the housing, so that the heat-dissipating element is confined to the opening without the risk of separating therefrom.

3. The electronic device having heat-dissipating structure as claimed in claim 1, wherein the thermal conductive element is a type of thermal grease.

4. The electronic device having heat-dissipating structure as claimed in claim 1, wherein the thermal conductive element is selected from the group consisting of a thermal pad, a heat-conducting post, and a heat-conducting block.

5. The electronic device having heat-dissipating structure as claimed in claim 1, further comprising an identification member being disposed on the first surface of the heat-dissipating element to expose from the housing via the opening.

6. The electronic device having heat-dissipating structure as claimed in claim 1, wherein the first surface of the heat-dissipating element has a size smaller than or equal to that of the opening.

7. The electronic device having heat-dissipating structure as claimed in claim 1, wherein the housing includes a first housing and a second housing; the first and the second housing being closed to each other to define the receiving space between them, and the PCB and the electronic component being located in the receiving space.
